(19) United States
(12) Patent Application Publication
(10) Pub. No.: US 2004/0178483 A1
(43) Pub. Date: Sep. 16, 2004

(54) Method of packaging a quad flat no-lead semiconductor and a quad flat no-lead semiconductor

(76) Inventors: Cheng-Ho Hsu, Kaohsiung (TW); Yi-Hua Chang, Feng-Shan City (TW)

Correspondence Address: Attn: Thomas E. Sisson, Jackson Walker L.L.P., Suite 2100, 112 E. Pecan Street, San Antonio, TX, 78205, US

(21) Appl. No.: 10/387,266

(22) Filed: Mar. 12, 2003

(51) Int. Cl. H01L 23/02

(52) U.S. Cl. 257/678; 257/735

(57) ABSTRACT

A method of packaging a QFN semiconductor uses a metal frame having multiple component carriers consisting of die pads and leads attached to a tape. Dies are respectively attached to and wire bonded to the component carriers. A glue wall is formed around all of the component carriers on the metal frame. When the transparent encapsulant is poured inside the glue wall, the dies and the component carriers are covered. After the tape is removed, the component carriers are cut out of the metal frame to complete the QFN semiconductors. Therefore, the method can increase the quantity and quality of QFN semiconductors produced without regard to the size of the individual QFN semiconductors.

### BACKGROUND OF THE INVENTION

1. Field of the Invention

The present invention relates to a method of packaging a quad flat no-lead (QFN) semiconductor and a quad flat no-leaded (QFN) semiconductor, and more particularly to a QFN semiconductor that is less expensive and has good quality.

2. Description of Related Art

With reference to FIGS. 4A to 4G, a conventional method of packaging a QFN semiconductor includes (a) attaching a metal carrier (50) with a die pad (52) and multiple leads (53) to a tape (51); (b) attaching a mold (80) to the tape (51) around the metal carrier (50); (c) attaching a die (60) to the die pad (52) and bonding wires to the leads (53); (d) pouring a transparent encapsulant (70) into the mold (80); (e) removing the tape (51) after the transparent encapsulant (70) solidifies; and (g) removing the mold (80). The metal carrier (50) has a rectangular die pad (52) and multiple isolated leads (53). The rectangular die pad (52) has four edges (not numbered) and the multiple isolated leads (53) are near the four edges of the die pad (52). The mold (80) defines the QFN semiconductor's size. The transparent encapsulant (70) covers the die (60) and the metal carrier (50).

The forgoing packaging method still has some problems that adversely impact packaging quality of the small size QFN semiconductor. The problems include the following.

(1) Limitations on how small (smaller than 5 mm×5 mm) a semiconductor can be. To fabricate small size semiconductors as a chip scale package (CSP), the transparent encapsulant (70) needs to be very thin. According to the steps of the forgoing method, the mold (80) is attached to the tape (51) to define the size of the QFN semiconductor before bonding the die (60) and the metal carrier (53), so the mode (80) must be big enough to do the wire bonding. Therefore, using the mold (80) to define the size of the QFN semiconductor is a significant restriction on how small a QFN semiconductor can be.

(2) Different size molds (80) are required. The mold (80) is attached to the tape (51) to define the size of the QFN semiconductor. Therefore, different size molds (80) are required to form different size QFN semiconductors.

(3) The mold (80) is not cheap. The mold (80) has to be fabricated with a specific surface to keep the encapsulant from strongly bonding with the mold (80) so the mold (80) can easily be removed from the encapsulant (70), so the mold (80) is not cheap.

(4) Weak bond between the metal carrier (50) and the transparent encapsulant (70). The die pad (52) and the leads (53) are all connected by the encapsulant. The die pad (50) and each lead (53) are rectangular and have a top, a bottom and sides. The bottoms of the die pad (52) and the leads (53) are entirely attached on the tape (51) so the transparent encapsulant (70) does not cover the bottoms. Therefore, the bond between the encapsulant (70) and the die pad (52) or the lead (53) is weak. When the bond is weak, the encapsulant (70) easily strips from the metal carrier (50) and moisture can penetrate the die (60) to cause bad packaging quality.

The present invention provides a method of packaging a QFN semiconductor and a QFN semiconductor to mitigate or obviate the aforementioned problems.

### SUMMARY OF THE INVENTION

The main objective of the invention is to provide a method of packaging a QFN semiconductor that can package a small size QFN semiconductor.

Another objective of the invention is to provide a packaging method that can increase the quantity of the packaged QFN semiconductors.

Other objectives, advantages and novel features of the invention will become more apparent from the following detailed description when taken in conjunction with the accompanying drawings.

### BRIEF DESCRIPTION OF THE DRAWINGS

FIGS. 1A to 1G are cross sectional side plan views depicting the stages of packaging multiple QFN semiconductors in accordance with the present invention;

FIG. 2 is an enlarged cross sectional side plan view of a QFN semiconductor in accordance with the present invention;

FIG. 3 is a top plan view of the QFN semiconductor in FIG. 2; and

FIGS. 4A to 4G are cross sectional side plan views depicting the conventional stages of packaging a conventional QFN semiconductor in accordance with the prior art.

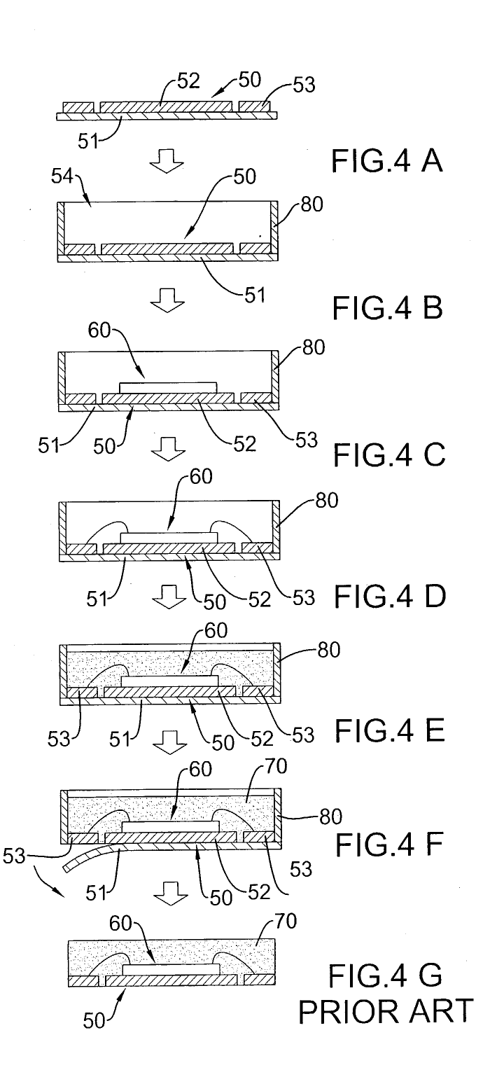

### DETAILED DESCRIPTION OF THE PREFERRED EMBODIMENT

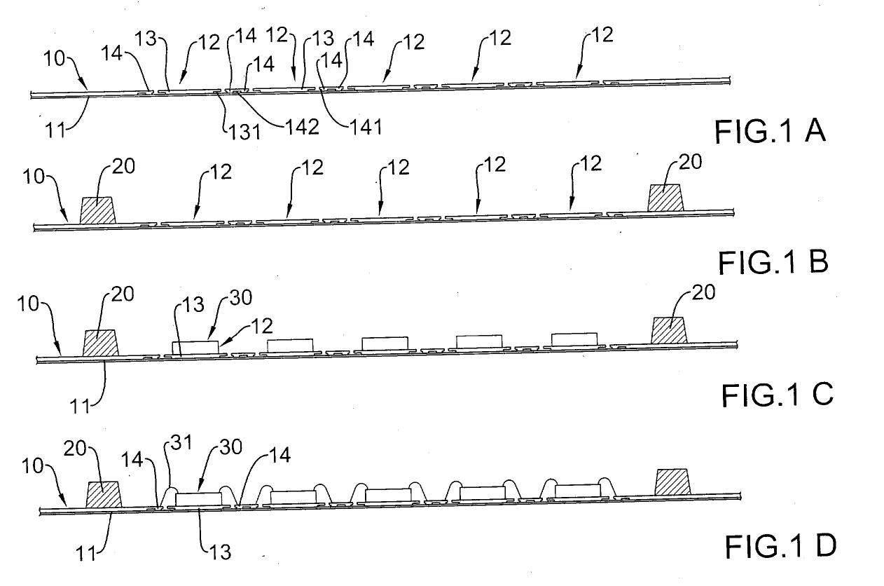

With reference to FIGS. 1A to 1G, a method of packaging many QFN semiconductors at the same time comprises steps of (a) providing a metal frame (10) attached to a tape (11); (b) forming a glue wall (20) on the metal frame (20); (c) attaching dies (30); (d) wire bonding each die (30); (e) pouring transparent encapsulant (40) onto the frame (10); (f) removing the tape (11); and (g) cutting out component carriers (12).

The metal frame (10) in the step (a) includes multiple component carriers (12). Each component carriers. (12) has a die pad (13) with four edges (not numbered) and multiple isolated leads (14) near the four edges of the die pad (13).

In step (b), the glue wall (20) is formed around all of the component carriers (12) on the metal frame (20).

In step (c), the dies (30) are attached respectively to the corresponding die pads (13) of the component carriers (12).

In step (d), a wire (31) is bonded to each lead (14) in each component carrier (12) and to each die (30) corresponding to the leads (14).

In step (e), the transparent encapsulant (40) is poured onto the frame (10) inside the glue wall (20) to cover all of the dies (30), die pads (13) and leads (14).

In step (f), the tape (11) attached to the metal frame (10) is removed to facilitate fabrication of individual QFN semiconductors.

In step (g), each component carrier (12) cut out of the frame (10) includes a die (13), the corresponding leads (14), the lead wires (31) and the transparent encapsulant (40) forms an individual QFN semiconductor.

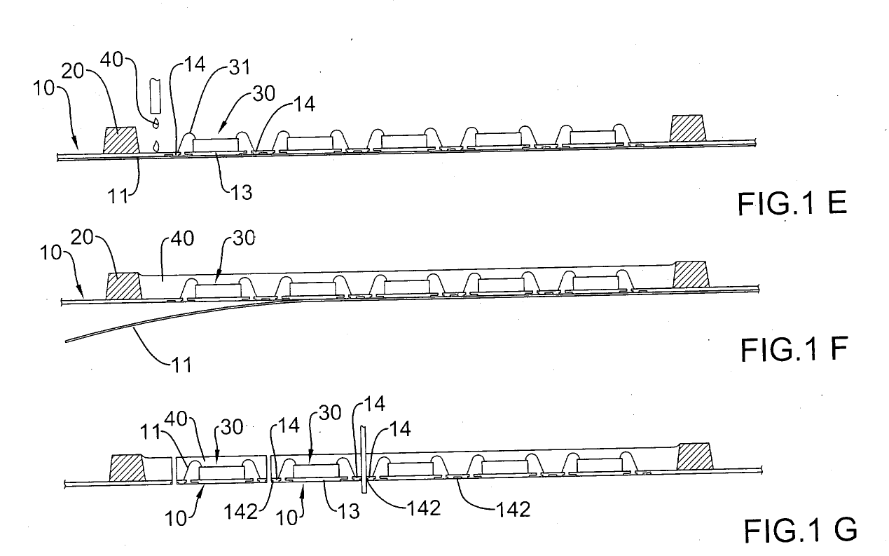

To further securely connect the transparent encapsulant (40) to the metal frame (10), with further reference to FIG. 2, each die pad (13) and isolated lead (14) provided in step (a) may be etched to define recesses (131, 141) that face the tape (11). In step (e), the recesses (131, 141) in the die pad (13) and the leads (14) will be filled with the transparent encapsulant (40) to securely connect the transparent encapsulant (40) to the metal frame (10).

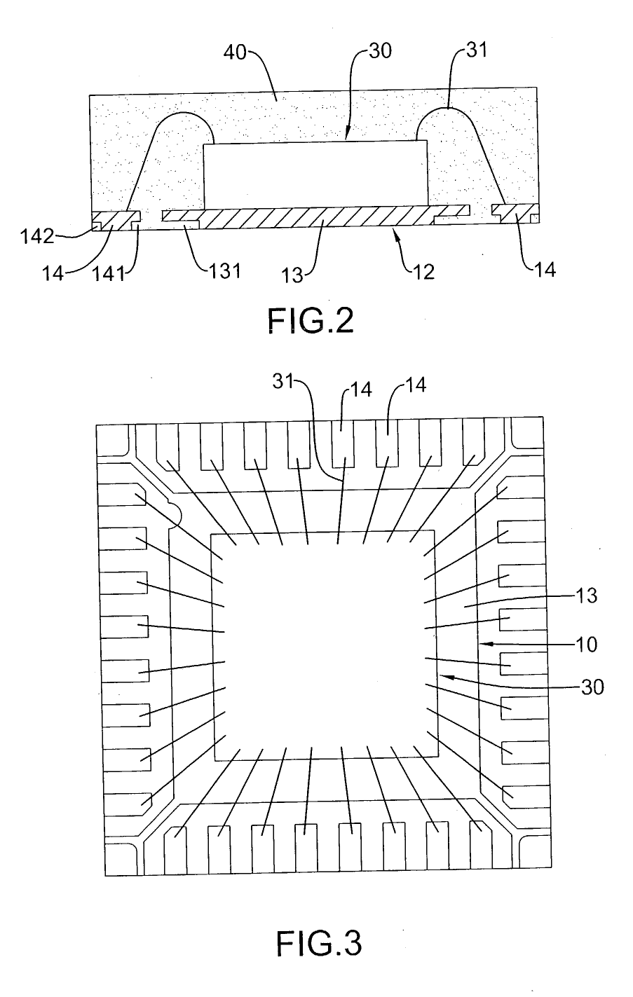

Again, the leads (14) of adjacent component carriers (12) can be connected together, so a recess (142) that faces the tape (11) is etched in the leads (14) at joints where they are connected together to make the leads (14) thinner at the joints. Therefore, the component carriers (12) can be easily separated from each other in step (g).With reference to FIG. 2, each QFN semiconductor fabricated by the forgoing method comprises a component carrier (12), a die (30), lead wires (31) and transparent encapsulant (40). With further reference to FIG. 3, the component carrier (12) has a die pad (13) and multiple isolated leads (14). The die pad (13) is rectangular and has four edges (not numbered), a top (not numbered), a bottom (not numbered) and a rectangular recess (131). The rectangular recess (131) is defined on the bottom of the die pad (13) at the edges. The multiple leads (14) are near the four edges of the die pad (13). Each lead (14) is rectangular, has a top (not numbered), a bottom (not numbered), an inside edge (not numbered) and an outside edge (not numbered) and may have an inside recess (141) and an outside recess (142). The inside edge of each lead (14) faces the die pad (13). The outside edge of each lead (14) faces away from the die pad (13). The inside recess (141) is defined on the bottom of each lead (14) at the inside edge. The outside recess (142) is defined on the bottom of each lead (14) at the outside edge. The die (30) is attached to the die pad (13) and bonded to the leads (14) with individual lead wires (31).

The transparent encapsulant (40) covers the die (30) and the leads (14) and fills the recesses (131, 141, 142) on the bottom of the component carrier (12), specifically the recess (131) around the die pad (13) and the inside and outside recesses (141, 142) on each lead (14). Other portions of the bottom of the die pad (13) and the leads (14) are exposed so the QFN semiconductor can be attached to a printed circuit board (PCB). The QFN semiconductor is an image sensor.

Since the transparent encapsulant (40) covering the tops of the die pad (13) and the leads (14) also covers the recesses (131, 141, 142) on the bottoms of the die pad (13) and the leads (14), the bond between the transparent encapsulant (40) and the die pad (13) and the leads (14) is strong. The transparent encapsulant (40) will not easily peal off of the component carrier (12). The QFN semiconductor can prevent moisture from contaminating the die (30).

Even though numerous characteristics and advantages of the present invention have been set forth in the foregoing description, together with details of the structure and function of the invention, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. A method of packaging a QFN semiconductor, comprising:
(a) providing a metal frame attached to a tape, where the metal frame includes multiple component carriers and each component carrier has a die pad with four edges and multiple isolated leads near the four edges of the die pad, wherein each die pad and isolated lead are etched to define recesses that face the tape;
(b) forming a glue wall on the metal frame around all of the component carriers on the metal frame;
(c) attaching dies to the corresponding die pads of the component carriers;
(d) bonding a lead wire to each lead and the corresponding die of each component carrier;
(e) pouring transparent encapsulant onto the metal frame inside the glue wall to cover all of the dies, the die pads, and the leads, wherein the recesses in the die pad and the leads are filled with the transparent encapsulant to securely connect the transparent encapsulant to the metal frame;
(f) removing the tape from the metal frame; and
(g) cutting out each component carrier including the die, the wire leads and transparent encapsulant to fabricate individual QFN semiconductors.

2. The method as claimed in claim 1, wherein the leads of adjacent component carriers are connected together and a recess that faces the tape is etched in the leads at joints where they are connected together to make the leads thinner at the joints.

3. A QFN semiconductor, comprising:
a component carrier having
a rectangular die pad with four edges, a top, a bottom and a rectangular recess on the bottom at the edges of the die pad; and
multiple isolated leads near the four edges of the die pad where each lead is rectangular and has a top, a bottom, an inside edge and an outside edge, wherein an inside recess is defined on the bottom of the lead at the inside edge and an outside recess is defined on the bottom of the lead at the outside edge;
a die attached to the top of the die pad;
lead wires bonded to the isolated leads and the die; and
a transparent encapsulant covering the die, the top of the die pad, the top of each isolated lead, wherein the transparent encapsulant fills the recesses on the bottom of the die pad and each lead.
